(19) United States
(12) Patent Application Publication
(10) Pub. No.: US 2002/0100863 A1
(43) Pub. Date: Aug. 1, 2002

(54) Optical image scanner with color and intensity compensation during lamp warmup

(76) Inventor: Kurt E. Spears, Fort Collins, CO (US)

Correspondence Address: HEWLETT-PACKARD COMPANY, Intellectual Property Administration, P.O. Box 272400, Fort Collins, CO, 80527-2400, US

(21) Appl. No.: 09/772,714

(22) Filed: Jan. 30, 2001

(51) Int. Cl. H01L 27/00

(52) U.S. Cl. 250/208.1

(57) ABSTRACT

An image scanner has a calibration strip, preferably the full width of the scanline, that is visible to a photosensor array continuously during a scan. For example, the calibration strip may be on a moving carriage. At least one separate array of photosensors is used to continuously monitor the intensity, and optionally color, of the illumination, along the calibration strip, during a scan. If color is monitored, preferably separate compensation is provided for every color. As a result, scanning can start as soon as the lamp provides sufficient light for scanning, without waiting for the lamp to stabilize.

### FIELD OF INVENTION

This invention relates generally to image scanners and more specifically to compensation for changes in intensity and color during warm up of a lamp used for image scanning.

### BACKGROUND OF THE INVENTION

Image scanners convert a visible image on a document or photograph, or an image in a transparent medium, into an electronic form suitable for copying, storing or processing by a computer. An image scanner may be a separate device, or an image scanner may be a part of a copier, part of a facsimile machine, or part of a multipurpose device. Reflective image scanners typically have a controlled source of light, and light is reflected off the surface of a document, through an optics system, and onto an array of photosensitive devices. The photosensitive devices convert received light intensity into an electronic signal. Transparency image scanners pass light through a transparent image, for example a photographic positive slide, through an optics system, and then onto an array of photosensitive devices. The optics system focuses at least one line, called a scanline, on the image being scanned, onto the array of photosensitive devices.

In some configurations, the light source is a long tube providing a narrow band of light which extends to each edge of the document for one dimension, or beyond the edges. For electric discharge lamps, such as cold-cathode fluorescent lamps, intensity and color is a function of power and temperature. The temperature of the vapor or gas, and the phosphors, indirectly affects intensity. Because of thermal time constants in the lamp, when such a lamp is first powered on, light intensity and color along the length of the tube do not stabilize uniformly. Light intensity and color vary dynamically along the length of the tube until the overall temperature of the light source stabilizes, which may be on the order of many minutes. Document scanners using such a light source typically wait for some stabilization before scanning the document.

Image scanners may wait open-loop for a worst case lamp warm-up time before initiating a scan. For typical light sources, the required time is on the order of tens of seconds. In general, such a delay adds unnecessary additional time to every scan. Such a delay is particularly inappropriate if the lamp is already warm. Alternatively, some image scanners leave the lamp on continuously. Fluorescent lamps for image scanners are relatively low power, so that continuous usage does not waste much power, but consumers may be concerned about the waste of power and possible reduced lifetime. Some image scanners overdrive the lamp initially to decrease the warm-up time (see U.S. Pat. No. 5,907,742; see also U.S. Pat. No. 5,914,871). In '742, the lamp current is also maintained at a low level between scans to keep the lamp warm In some image scanners, the lamp is periodically turned on for a few minutes every hour during long periods of inactivity (see U.S. Pat. No. 5,153,745). In some scanners, the lamp is enclosed by a heating blanket (except for an aperture for light emission), which keeps the lamp continuously warm (see U.S. Pat. No. 5,029,311). Another approach is to monitor a lamp parameter during warm-up, and delay scanning until the parameter is stable. For example, see U.S. Pat. No. 5,336,976, in which power to the lamp is monitored, and scanning is delayed until power stabilizes.

Even after the lamp is warm, there is some intensity variation over time. In addition, even with a warm lamp, intensity varies along the length of the lamp. In particular, for a warm lamp, the center region of the lamp is typically brighter than the ends of the lamp. Reflective document scanners and copiers commonly have a transparent platen on which a document is placed for scanning. Reflective document scanners and copiers commonly provide a fixed-position calibration strip, along a scanline dimension, typically along one edge of the bottom surface of the platen. This calibration strip is used to compensate for variation in sensitivity of individual photosensors (photo-response non-uniformity or PRNU), and for variation in light intensity along the length of the scanline. See, for example, U.S. Pat. No. 5,285,293. If sensor calibration is made while the intensity of the light source is still dynamically changing, an inaccurate sensor calibration may result. As a result, even though the intensity of the light source may be stable for most of the scan, the sensors will be inaccurate for the entire scan because of inaccurate initial calibration. Accordingly, it is common to wait for the lamp to stabilize before doing the PRNU calibration.

The human eye contains three different kinds of color receptors (cones) that are sensitive to spectral bands that correspond roughly to red, green, and blue light. Specific sensitivities vary from person to person, but the average response for each receptor has been quantified and is known as the “CIE standard observer.” Accurate reproduction of color requires a light source that has adequate intensity in each of the spectral response ranges of the three types of receptors in the human eye. Typically, given a set of numerical values for photosensor responses for one pixel, for example, red, green, and blue, the numbers are mathematically treated as a vector. The vector is multiplied by a color transformation matrix to generate a different set of numbers. In general, the coefficients in the color transformation matrix compensate for differences between the response of photosensors and the response of the CIE standard observer, and the coefficients in the matrix may include compensation for the spectrum of the illumination source. See, for example, U.S. Pat. Nos. 5,793,884, and 5,753,906. An example output of the matrix is a set of coordinates in the CIE L*A*B* color space. Typically, matrix coefficients are fixed, and are obtained in a one-time factory calibration using a stable illumination source. With fixed matrix values, it is typically assumed that the spectrum of the illumination source is constant along the length of the lamp, and constant during the scan. Accordingly, it is common to wait for the lamp to stabilize before scanning to ensure that the spectrum of the illumination is close to the spectrum assumed in the matrix values.

Reflective document scanners and copiers also commonly provide a second calibration strip along one edge of the platen in the direction of scanning travel. This second calibration strip is used to compensate for variation in lamp intensity during a scan. Essentially, it is assumed that once the lamp is warm, then relative intensity variation along the length of the lamp is constant, so it is sufficient to measure intensity near one end of the lamp. See, for example, U.S. Pat. No. 5,278,674. It is also known to monitor the color of the lamp (again, just near one end), for gain compensation. For scanners having a moving carriage, with the lamp in the moving carriage, it is also known to provide a small tab on the moving carriage for intensity monitoring. See U.S. Pat. No. 6,028,681. Similarly, for a hand held scanner, it is known to provide small intensity calibration areas within the scanner, near the ends of the light source, and the entire scanner moves relative to a document being scanned. See U.S. Pat. No. 5,995,243.

There is an ongoing need to reduce the delay associated with lamp warm-up, and to provide PRNU calibration, intensity compensation, and color compensation, during scanning.

### SUMMARY OF THE INVENTION

A scanner has a calibration strip, preferably substantially the full width of the scanline, that is visible to a photosensor array continuously during a scan. For example, if the lamp is in a moving carriage, the calibration strip may be on the moving carriage. At least one separate array of photosensors is used to continuously monitor the intensity of the illumination, along the calibration strip, during a scan. Preferably, the separate array of photosensors also monitors the color of the illumination along the calibration strip. If color is monitored, preferably separate compensation is provided for every color. As a result, scanning can start as soon as the lamp provides sufficient light for scanning, without waiting for the lamp to stabilize. It is not necessary to keep the lamp on, or to keep the lamp warm. In addition, the system provides better scanning accuracy, by providing better compensation during a scan.

### BRIEF DESCRIPTION OF THE DRAWINGS

FIG. 1 is a simplified cross section block diagram of an example embodiment of a scanner, in accordance with the invention.

FIG. 2 is a simplified top view of some of the elements of FIG. 1.

FIG. 3 is a block diagram of an example embodiment of a compensation system, in accordance with the invention.

FIG. 4 is a block diagram of an example embodiment of a compensation system including compensation for color, in accordance with the invention.

FIG. 5 is a block diagram of an alternative example embodiment of a compensation system including compensation for color, in accordance with the invention.

FIG. 6 is a simplified cross section block diagram of an example alternative embodiment of a scanner as in FIG. 1, with a moveable CCD array, in accordance with the invention.

FIG. 7 is a simplified cross section block diagram of an example alternative embodiment of a scanner as in FIG. 1, with an optical wedge.

### DETAILED DESCRIPTION OF THE PREFERRED EMBODIMENT OF THE INVENTION

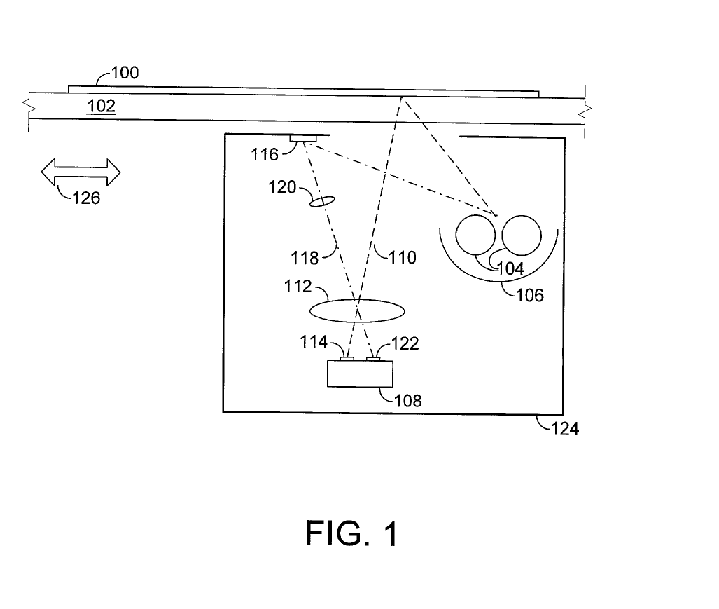

In FIG. 1, a document 100 is positioned face down on a transparent platen 102. A pair of lamps 104 are partially enclosed in a reflector 106. A photosensor array 108 receives light from a narrow scanline on the document 100. Light ray 110 represents light from the lamps 104, diffusely scattered from the document 100, through a focusing lens 112, onto an array of photosensors 114. The scanner illustrated in FIG. 1 also includes a calibration strip 116. Light ray 118 represents light from the lamps 104, diffusely scattered from the calibration strip 116, through a lens 120 (optional), through the focusing lens 112, and onto an array of photosensors 122. The lamps, photosensors, lenses, and calibration strip 116 are all mounted in or on a moveable carriage 124. For scanning, the carriage 124 moves relative to the document 100, as depicted by arrows 126. Note, in particular, that a separate array of photosensors 122 is provided for monitoring light from the calibration strip 116. Note also that the calibration strip 116 travels with the carriage 124, in a fixed spatial relationship relative to the photosensor array 122, and relative to lamps 104, so that the photosensor array 122 receives light continuously from the calibration strip 116 during scanning. Scanning can start as soon as the lamp provides sufficient light for scanning, without waiting for the lamp to stabilize. It is not necessary to keep the lamp on, or to keep the lamp warm. In addition, the system provides better scanning accuracy, by providing better compensation (entire length of scanline, and color) during a scan.

Photosensor array 122 may be an array dedicated to monitoring the lamp. Alternatively, as will be discussed in more detail below, photosensor array 122 may be one of several arrays that are also used for document imaging. If photosensor array 122 is dedicated to monitoring the lamp, it may be a separate assembly. In particular, array 122 and array 114 may be fabricated on separate integrated circuit die, and array 122 and array 114 may be mounted on separate substrates.

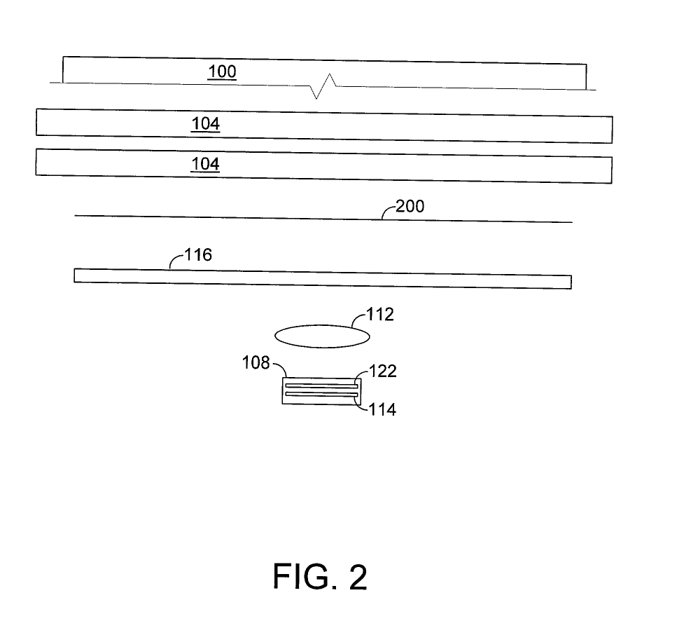

FIG. 2 is a top view of some the elements of FIG. 1, illustrating relative spatial relationships. Elements in FIG. 2 are not to scale. In FIG. 2, note that the lamps 104 are typically longer than the width of a document 100. Note that the photosensor assembly 108 is typically small relative to the width of a document.

Line 200 depicts a scanline that is focused onto array 114 by lens 112. Note that the length of the scanline 200 is typically less than the width of a document. Note also that the calibration strip 116 is preferably at least as long as the scanline 200. The calibration strip 116 does not have to be continuous, and does not have to be as long as the scanline. It is preferable, however, that the calibration strip provide lamp intensity and color information at a sufficient number of locations to characterize any nonuniformity of intensity and color along the length of the illumination source, within the length of the scanline. It particular, for many lamps, it is important to monitor at least near one end of the lamp and the region near the center of the lamp.

Note that two lamps 104 are illustrated in FIGS. 1 and 2, but it is common to have a single lamp. Note also that the focal length of a focusing lens assembly typically requires multiple mirrors to fold the light path within the carriage. FIG. 1 illustrates a reflective scanner, in which light is reflected off an opaque document for scanning. The invention is equally applicable to a transparency scanner, in which light passes through a transmissive medium, and in which the light is also routed to a calibration strip visible by a line of photosensors. Note also that light received by the photosensor arrays (114, 122) is not from specular reflections, but rather is from diffuse scattered light. Array 114 typically comprises three lines of photosensors, one line receiving red wavelengths, one line receiving green wavelengths, and one line receiving blue wavelengths. However, there are many variations, for example, there may be more than three lines, or at least one line may receive white light, or other colors may be sensed.

The array of photosensors 122 may be a single line receiving white light. Preferably, the array of photosensors 122 has separate sensors for each color of interest. For example, if array 114 comprises separate lines receiving red, green, and blue light, then array 122 preferably has sensors receiving red, green, and blue light. These sensors may be in a single row, for example, with filters so that a first sensor receives red wavelengths, and second sensor receives green wavelengths, a third sensor receives blue wavelengths, with the pattern repeating along the line. Alternatively, array 122 may comprise multiple lines of photosensors, with for example, one line receiving red wavelengths, one line receiving green wavelengths, and one line receiving blue wavelengths. Note that it is not necessary for array 122 to have the same native optical sampling rate as array 114. For example, array 114, in conjunction with the lens 112, may have a native optical sampling rate of 600 pixels per inch (24 pixels per mm), whereas for light monitoring, array 122 may only need, for example, 10 pixels per inch. The actual requirement depends on the variability of the light intensity and color along the length of the lamps 104, but typically a relatively coarse optical sampling rate is sufficient for light monitoring purposes. Note also that it is not necessary for the calibration strip 116 to be precisely focused at the array 122. Accordingly, lens 120 may not be necessary, particularly if lens 112 has a long focal length.

The photosensor array sensing the calibration strip may be fabricated on the same substrate as the photosensor array sensing the scanline. However, it is also suitable for the photosensor array sensing the calibration strip to be on a separate substrate, and possibly mounted in a separate package. For example, a completely separate light path could be used for calibration, and in particular, one that does not use lens 112. There are many alternative light path designs for which the invention is suitable. For example, instead of a lens, light pipes or optical fibers may be used. Hybrid designs are also possible. For example, light pipes or optical fibers could be used for viewing the calibration strip, and a lens could be used for viewing the document.

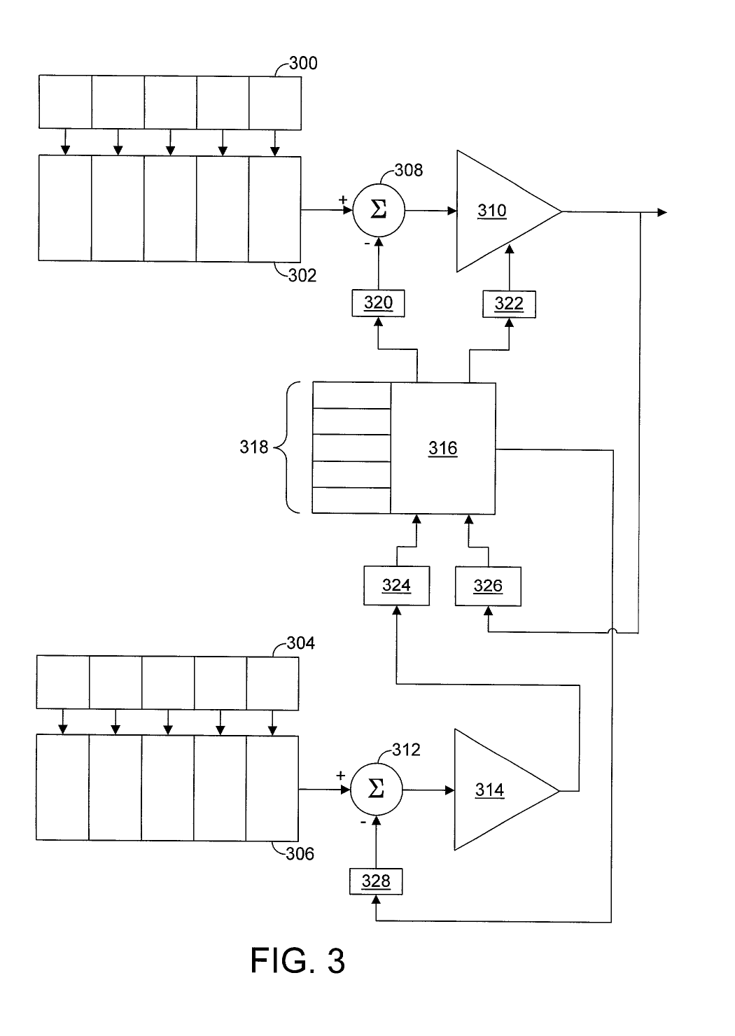

FIG. 3 illustrates a first example system for continuous compensation. For FIG. 3, assume that array 114, and array 122, in FIG. 1, each comprise a single line of photosensors receiving white light, and that the optical sampling rate for the array 122 is the same as the optical sampling rate for array 114. In FIG. 3, for document imaging, an array of photosensors 300 transfers charges to a charge shift register 302. For lamp monitoring, a second array of photosensors 304 transfers charges to a charge shift register 306. Charges from the document imaging charge shift register 302 are converted to voltages, and the voltages pass through a summing junction 308, and then to an amplifier 310. Charges from the lamp monitoring charge shift register 306 are converted to voltages, and the voltages pass through a summing junction 312, and then to an amplifier 314. A processor 316 has access to memory 318. Digital values from the processor 316 are converted to voltages by digital-to-analog converters 320, 322, and 328. Analog voltages from amplifiers 310 and 314 are converted to digital values by analog-to-digital converters 326 and 324 respectively. The processor 316, via digital-to-analog converters 320 and 328, provides dark noise correction voltages, which will be discussed in more detail below. The processor 316, via digital-to-analog converter 322, controls the gain of amplifier 310, which will be discussed in more detail below.

The arrangement in FIG. 3 is intended to illustrate functional relationships, and should not be interpreted as a literal implementation. In particular, the summing junctions 308 and 312, and the variable gain amplifier 310, are illustrated as analog operations to facilitate understanding, but all signal processing could be done digitally, either in a general purpose processor or in a specialized digital signal processor. Alternatively, all signal processing could be done as analog processes. In particular, analog values may be used to compensate analog gain. For example, instead of using the analog-to-digital converter 324, processor 316, and buffer memory 318, one could use an analog shift register to store charges from the lamp monitoring photosensors 304 (like shift registers 302 and 306). Then, buffered charges could be converted to voltages for control of amplifier gain. In addition, digital processing may be performed in a peripheral scanner, or raw image data may be sent to a host computer and the host computer may perform the functional equivalent of gain adjustments.

Even if a sensor is receiving no light, some thermal noise (called dark noise) may occur. It is common to measure thermal noise for each photosensor, with no illumination present, before scanning. The measured thermal noise is stored, and then subtracted from voltages from photosensors during scanning. In FIG. 3, thermal noise is measured for photosensors 300, before scanning, and the resulting values are stored in memory 318. Then, during scanning, as voltages are shifted to the summing junction 308, the processor 316 provides a corresponding thermal noise value that is subtracted from the voltage obtained during an image scan. Similarly, thermal noise may be measured for the lamp monitoring photosensors 304, before scanning, with no illumination, and the resulting values may be stored in memory. As lamp monitoring voltages are shifted to the summing junction 312, the processor 316 provides a corresponding thermal noise value that is subtracted from the voltage obtained during light monitoring. Thermal noise compensation for the lamp monitoring photosensors 304 is optional. If the lamp monitoring photosensors monitor light from a highly reflective calibration strip, then thermal noise may be insignificant relative to the signals obtained during lamp monitoring. However, as discussed below, it may be desirable for the calibration strip for light monitoring to be relatively dark, and in that case thermal noise compensation may be appropriate.

It is also common to provide a calibration strip (not illustrated in FIG. 1 or FIG. 2), along one edge of a platen supporting a document, which is used to provide photosensor sensitivity calibration before scanning (called photo-response-non-uniformity, or PRNU, calibration). PRNU calibration inherently includes anomalies due to photosensor sensitivity, dust or scratches, and non-uniform intensity. Intensity values are measured before scanning, with illumination, and amplifier gain compensation values are stored in memory. Then during scanning, the gain of the amplifier is modified, for each photosensor. In FIG. 3, before scanning, with illumination, intensity values are measured and read by the processor 316. The processor 316 then stores a gain compensation value in memory for each photosensor, which ensures that every voltage from amplifier 310, when scanning the PRNU calibration strip, is a constant value.

In accordance with the invention, PRNU calibration values are also obtained, before scanning, for lamp monitoring photosensors 304, and these values are also stored in memory. In accordance with the invention, the gain compensation values being sent to digital-to-analog converter 322 for modification of the gain of amplifier 310, are further modified during scanning, by PRNU values from the lamp monitoring photosensors 304, and by values, from the lamp monitoring photosensors 304, obtained during scanning. The overall resulting corrected data may have the following example form:

D(n,m)=[CCD(n,m)−DN(n)]*[PRNU(n)][(LM(n,0)/LM(n,m)] {Equation 1}

where:

D(n,m) is the corrected intensity for document imaging photosensor n, scanline m.

CCD(n,m) is the uncorrected intensity for document imaging photosensor n, scanline m.

DN(n) is the dark noise compensation value for document imaging photosensor n (constant for all m).

PRNU(n) is the PRNU gain compensation value for document imaging photosensor n (constant for all m)

LM(n,0) is the intensity value (optionally corrected for dark noise) from lamp monitoring photosensor n, measured at the same time as PRNU for the document imaging photosensors.

LM(n,m) is the intensity value (optionally corrected for dark noise) from lamp monitoring photosensor n, as appropriate for scanline m.

Exposure of one scanline typically occurs while charges from the previous scanline are being processed. Photosensor arrays 300 and 304 may be exposed at the same time. However, note that charges from the lamp monitoring photosensor array 304 must be processed and stored in buffer memory before information is available for compensation. Accordingly, digital information from array 304, obtained during one exposure, is used to modify the analog information from photosensor array 300 obtained during one or more later exposures.

In some parts of the present patent document, for simplicity of explanation, it is assumed that every scanline of the document is compensated by data from one corresponding exposure of the lamp monitoring photosensor array 304. Note, however, that it is not necessary to update compensation data for every scanline. For example, if the lamp intensity and lamp color changes are relatively slow compared to the time required to expose and process one scanline, then the data from one exposure of the photosensors for lamp monitoring can be used to compensate multiple consecutive scanlines. Alternatively, one exposure of the photosensors for lamp monitoring could be used to compensate one color, the next exposure could be used to compensate another color, and so forth.

Scanning speed may be limited by exposure time, or by processing time. Preferably, scanning is performed in one continuous motion. For example, in FIG. 1, preferably carriage 124 never has to stop during scanning. If lamp compensation data is obtained as one chunk of data every N scanlines, then there may be some risk that the carriage may have to pause while the lamp compensation data is being processed. If scanning speed is limited by exposure time, there may be time during each scanline to receive, and process, part, but not all, of the lamp compensation data. For example, for each scanline, 10% of the data for lamp compensation may be read. After ten scanlines, one full line of lamp compensation data is accumulated. Ten scanlines of document imaging data could be stored, and lamp compensation data could be applied after all the lamp compensation data has been accumulated. The lamp compensation data may also be interpolated. For example, assume the lamp monitoring photosensors and the document imaging photosensors are exposed for scanline m. The lamp compensation data is then processed during accumulation of document imaging data for scanlines m to m+10. The lamp monitoring photosensors and the document imaging photosensors are then exposed for scanline m+11. The lamp compensation data is then processed during accumulation of document imaging data for scanlines m+11 to m+20. Then, document imaging data for scanlines m to m+10 may be compensated by interpolating between lamp compensation data obtained at scanline m and compensation data obtained at scanline m+11.

If lamp intensity data is transferred from the lamp monitoring photosensors infrequently, then charges in the lamp monitoring photosensors may overflow. One solution is to provide overflow drains, either vertical drains or lateral drains. An alternative solution is to make the calibration strip relatively dark. For example, if the light received from the calibration strip is only 10% of the intensity required to saturate the lamp monitoring photosensors, then the lamp monitoring photosensors can accumulate charge over ten consecutive exposures without having to deal with overflow. If the lamp monitoring photosensors charge over a long period of time, then it may be appropriate to compensate for thermal noise, which is a function of time.

Note that the above gain compensation is only a first-order correction for color variation. Further compensation may be obtained by changing the coefficients in the color transformation matrix in real time, from pixel-to-pixel. Preferably, however, a lamp is chosen that does not require changes in the color transformation matrix.

There are many variations of photosensor assemblies, and the configuration of FIG. 3 may be varied accordingly. For a first example variation of FIG. 3, assume that there are multiple document imaging arrays 300, and only one lamp compensation array 304. For example, there may be a red document imaging array, a green document imaging array, and a blue document imaging array, and only one compensation array (receiving white light). Digital values from the one lamp compensation array are then used to adjust gains equally for three amplifiers for the imaging arrays. For a second variation of FIG. 3, assume that the example of FIG. 3, arrays 300 and 304 each receive red wavelengths, and that all the circuitry of FIG. 3, other than the processor 316 and memory 318, is repeated for green and blue wavelengths. Then, each color is compensated separately, continuously, during scanning.

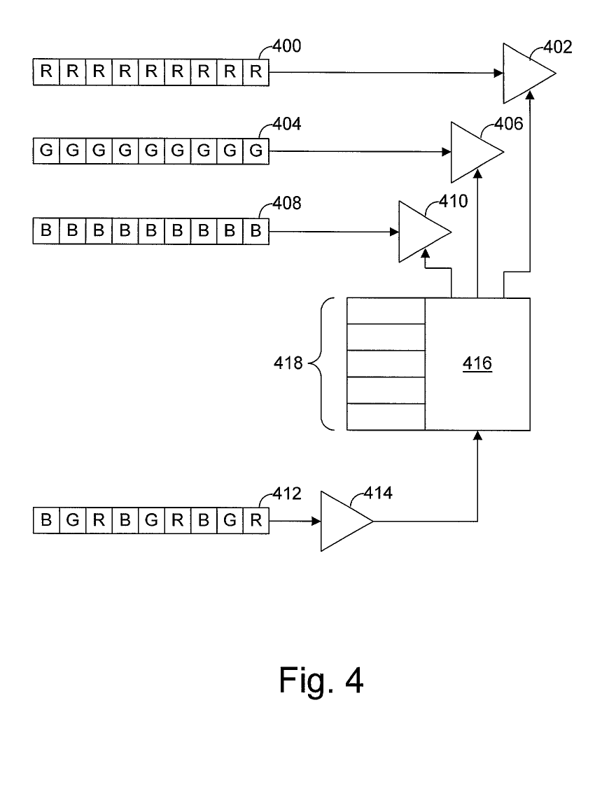

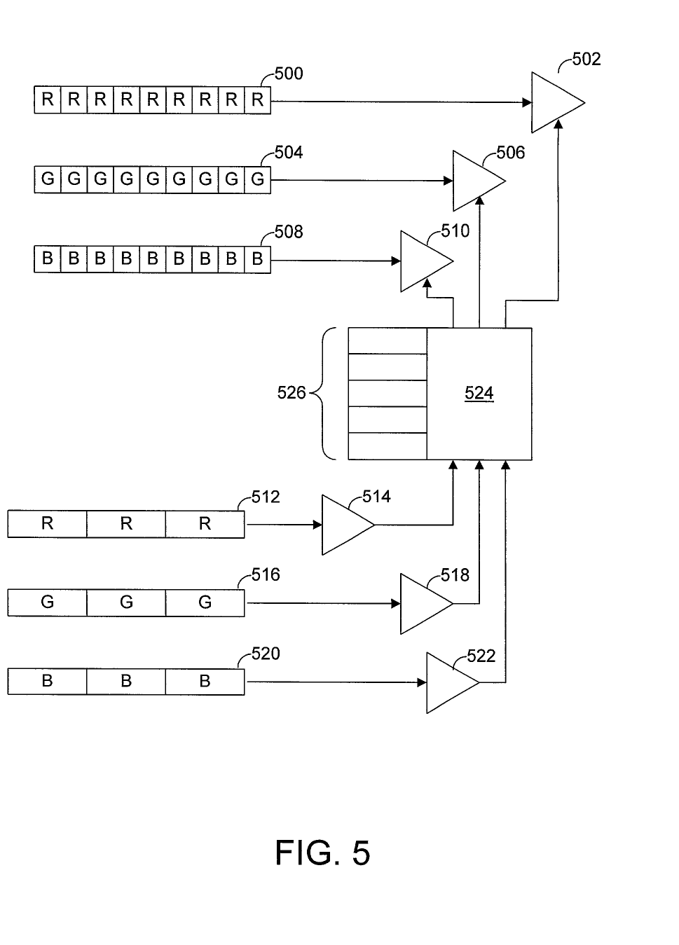

FIGS. 4 and 5 are additional variations of FIG. 3. In FIGS. 4 and 5, the optical sampling rate for the lamp monitoring array(s) is less than the optical sampling rate for the document imaging array(s). In FIGS. 4 and 5, summing junctions, analog-to-digital converters, and digital-to-analog converters have been omitted for simplicity of illustration. In FIG. 4, there are three arrays of photosensors for document imaging (400, 404, 408), and one array of photosensors 412 for lamp monitoring. Digital values from a processor 416 modify the gain of the amplifiers (402, 406, 410) for the document imaging arrays. For any one color, the optical sampling rate for the lamp monitoring array 412 is one-third the sampling rate for the document imaging array 400. Array 412 has the same number of photosensors as array 400, but in array 412, every third photosensor receives red light, every third photosensor receives green light, and every third photosensor receives blue light. Each digital value in the memory 418 may provide equal compensation for three consecutive charges from one imaging sensor array (400, 404, 408).

In FIG. 5, there are three arrays of document imaging photosensors (500, 504, 508) and three arrays of lamp monitoring photosensors (512, 516, 520). The optical sampling rate for each array of lamp monitoring photosensors is one-third the optical sampling rate for each array of document imaging photosensors. Digital values from processor 524 modify the gain of the amplifiers (502, 506, 508) for the document imaging arrays. Each digital compensation value in the memory 526 may provide equal compensation for three consecutive charges from one document imaging sensor array (500, 504, 508).

With a color separator, all document imaging photosensor arrays simultaneously image one scanline. With color filters, and with three document imaging arrays (for example as in FIG. 5, arrays 500, 504, and 508), three separate scanlines are imaged by the arrays. With color filters, for each scanline, buffer memory is required to save earlier scanned data until all colors have been scanned. Consider FIG. 5. There is a scanline that is first imaged by array 500, then by array 504, and then by array 508. Because of the separation in time, the data from arrays 500, 504 and 508, for one scanline, may be compensated by data from different lamp monitoring exposures for arrays 512, 516, and 520. For example, for each scanline, for each color, lamp compensation data may be obtained one exposure earlier. Therefore, for color filters, in FIG. 5, the scanlines being compensated are offset. For example, assume that, as seen on the document being scanned, that the red array 502 images a scanline that is separated by 3 scanlines from the scanline being imaged by the green array 506, and the green array 506 is separated by 3 scanlines from the scanline being imaged by the blue array 510. When the system is scanning, at exposure N, red data for scanline S, green data for scanline S+3, and blue data for scanline S+6, are all being compensated by lamp data obtained during exposure N−1.

Note that there are many variations of configurations for arrays that may in turn require variations of the examples shown in FIGS. 3-5. For example, it is known to provide two charge shift registers (and two amplifiers) for one photosensor array. The arrangement is sometimes called bilinear readout, or split-register readout. It is also known to stagger CCD photosensors (alternate photosensor elements are offset in opposite directions from a centerline) to partially compensate for the area loss between adjacent photosensors. Staggered photosensors typically require dual-sided charge shift registers (one charge shift register on each side of the staggered array), with two amplifiers. For these and other configurations, digital values from one lamp monitoring array may have to control gains for multiple amplifiers.

In the discussion of FIGS. 1-5, for simplicity of explanation, it is assumed that a separate array of photosensors is dedicated to lamp monitoring and compensation. It is known to provide multiple arrays, perhaps with multiple resolutions, where the function of all the arrays is for document imaging. If there are multiple arrays for document imaging, and only one document imaging array is used for any one scan, then an unused document imaging array can be used for lamp compensation. For example, in FIG. 1, assume that arrays 114 and 122 are both suitable for document imaging. Now, assume that assembly 108 is rotated 180 degrees horizontally, so that arrays 114 and 122 exchange positions as viewed in FIG. 1. That is, light ray 110 then impinges onto array 122, and light ray 118 then impinges onto array 114. Array 122 may then be used for document imaging, and array 114 may then be used for lamp compensation.

For a photosensor assembly as in FIG. 5, if the photosensor assembly is rotated as discussed above, then for any given scanline, the scanline is first imaged by array 520, then by array 516, and then by array 512. In the rotated state, data from arrays 520 and 516 must be buffered before combining with data from array 512.

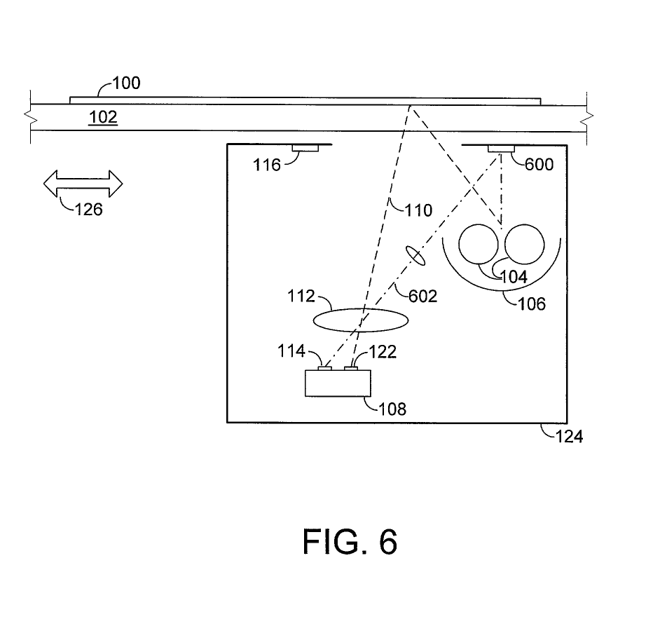

FIG. 6 illustrates an alternative example for using arrays for both imaging and for lamp compensation. FIG. 6 is a variation of FIG. 1. In FIG. 6, the photosensor assembly 108 has been mechanically translated to the left by the distance between array 114 and array 122. Light ray 110 then impinges on array 122 for document imaging. A second calibration strip 600 is imaged by array 114, as depicted by light ray 602, for lamp compensation.

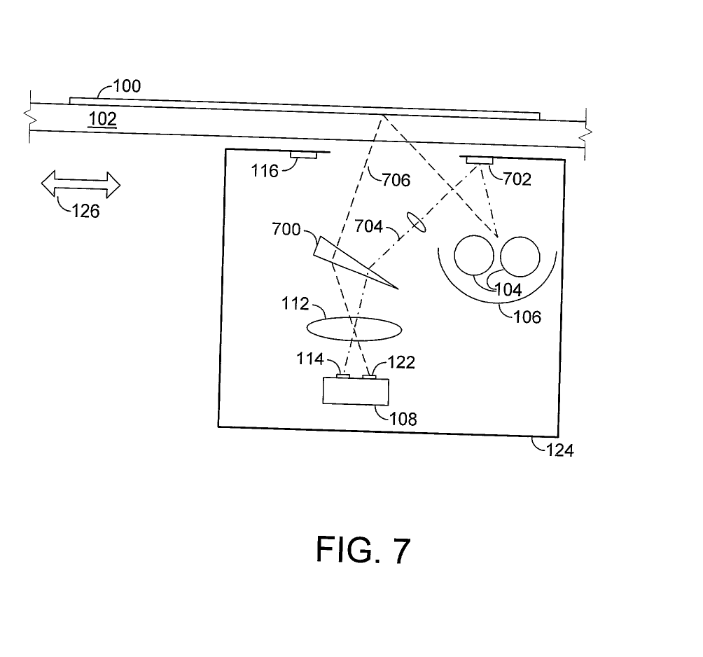

FIG. 7 illustrates still another alternative example for using arrays for both imaging and for lamp compensation. In FIG. 7, an optical wedge 700 has been inserted into the light path. Without the optical wedge, the light paths are as depicted in FIG. 1, with array 114 used for document imaging and array 122 used for lamp compensation. With the optical wedge 700 inserted, array 114 is used for lamp compensation (second calibration strip 702 and light ray 704), array 122 is used for document imaging (light ray 706). There are many alternative configurations, including use of mirrors, moving lenses, moving light pipes, moving optical fibers, and other devices suitable for altering the light paths.

The foregoing description of the present invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. An image scanner comprising:
a light source;
a calibration strip;
an array of photosensors receiving light, from at least a region near one end of the light source and from a region near the center of the light source, scattered from the calibration strip; and
the calibration strip having a fixed spatial relationship relative to the light source, and relative to the array of photosensors.

2. The image scanner of claim 1, the array of photosensors further comprising photosensors receiving at least two different bands of wavelengths of light.

3. The image scanner of claim 1, the array of photosensors being a first array of photosensors, the image scanner further comprising:
a second array of photosensors receiving light, from the light source, scattered from a scanline.

4. The image scanner of claim 3, further comprising:
outputs from the first array of photosensors being used to modify outputs from the second array of photosensors, during scanning.

5. The image scanner of claim 3, where a native optical sampling rate for the second array of photosensors is different than a native optical sampling rate for the first array of photosensors.

6. The image scanner of claim 3, further comprising a third array of photosensors receiving light, from the light source, scattered from the calibration strip, where photosensors in the third array of photosensors receive a different band of wavelengths of light than the first array of photosensors.

7. The image scanner of claim 3, wherein the first and second arrays of photosensors are on separate integrated circuit die.

8. The image scanner of claim 3, wherein the first and second arrays of photosensors are on separate substrates.

9. An image scanner comprising:
a light source;
a calibration strip;
a first array of photosensors receiving light, from the light source, scattered from the calibration strip;
a second array of photosensors receiving light, from the light source, scattered from a scanline;
the first array of photosensors receiving light from portions of the light source sufficient to enable the first array of photosensors to characterize the light received from the light source over substantially the length of the scanline;
the calibration strip having a fixed spatial relationship relative to the light source, and relative to the first array of photosensors; and
outputs from the first array of photosensors being used to modify outputs from the second array of photosensors, during scanning.

10. The image scanner of claim 9, the first array of photosensors further comprising photosensors receiving at least two different bands of wavelengths of light.

11. The image scanner of claim 9, further comprising a third array of photosensors receiving light, from the light source, scattered from the calibration strip, where photosensors in the first array of photosensors receive a different band of wavelengths of light than the third array of photosensors.

12. The image scanner of claim 9, where a native optical sampling rate for the first array of photosensors is different than a native optical sampling rate for the second array of photosensors.

13. An image scanner, comprising:
a light source;
a calibration strip;
a first array of photosensors;
a second array of photosensors, the second array of photosensors having a fixed spatial relationship relative to the first array of photosensors;
the first and second arrays of photosensors rotatable;
wherein at a first rotation position of the first and second arrays of photosensors, the first array of photosensors receives light, from the light source, scattered from the calibration strip, and the second array of photosensors receives light, from the light source, scattered from a scanline; and
wherein at a second rotation position of the first and second arrays of photosensors, the first array of photosensors receives light, from the light source, scattered from the scanline, and the second array of photosensors receives light, from the light source, scattered from the calibration strip.

14. An image scanner, comprising:
a light source;
a first calibration strip;
a second calibration strip;
a first array of photosensors;
a second array of photosensors, the second array of photosensors having a fixed spatial relationship relative to the first array of photosensors;
the first and second arrays of photosensors capable of being translated in position;
wherein at a first translation position of the first and second arrays of photosensors, the first array of photosensors receives light, from the light source, scattered from the first calibration strip, and the second array of photosensors receives light, from the light source, scattered from a scanline; and
wherein at a second translation position of the first and second arrays of photosensors, the first array of photosensors receives light, from the light source, scattered from the scanline, and the second array of photosensors receives light, from the light source, scattered from the second calibration strip.

15. An image scanner comprising:
a light source;
a first calibration strip;
a second calibration strip;
a first array of photosensors;
a second array of photosensors;
an optical path diverter;
wherein for a first position of the optical path diverter, the first array of photosensors receives light, from the light source, scattered from a scanline, and the second array of photosensors receives light, from the light source, scattered from the first calibration strip; and
wherein for a second position of the optical path diverter, the first array of photosensors receives light, from the light source, scattered from the second calibration strip, and the second array of photosensors receives light, from the light source, scattered from the scanline.

16. A method of compensation for illumination variation in an image scanner, comprising:
initiating image scanning, as soon as sufficient illumination is available, without waiting for illumination to stabilize;
monitoring the intensity of the illumination, along substantially the entire length of a scanline, during scanning; and
modifying an output of an imaging array, during scanning, in response to the intensity being monitored.

17. The method of claim 16, further comprising:
monitoring the color of the illumination, along substantially the entire length of the scanline, during scanning.

18. The method of claim 16, further comprising:
measuring, an initial intensity of the lamp, at a position corresponding to a particular pixel on a scanline;
measuring, at time T, an intensity of the lamp, at the position corresponding to the particular pixel on the scanline, during scanning;
measuring, at time T, the intensity at the particular pixel on the scanline;
correcting the intensity of the particular pixel for thermal noise; and
multiplying the corrected intensity of the particular pixel times the initial intensity of the lamp divided by the intensity of the lamp at time T.

19. The method of claim 18, further comprising:
correcting the measurement of the initial intensity of the lamp for thermal noise; and
correcting the measurement of the intensity of the lamp at time T for thermal noise.

20. The method of claim 16, wherein each time the step of monitoring the intensity of illumination is performed, the following step is performed more than one time:
measuring intensity values along a scanline.

21. A method of compensation for illumination variation in an image scanner, comprising:
initiating image scanning, as soon as sufficient illumination is available, without waiting for illumination to stabilize;
measuring the intensity of the illumination, a first time, along substantially the entire length of a scanline, during scanning;
storing outputs of an imaging array for multiple scanlines;
measuring the intensity of illumination, a second time, along substantially the entire length of a scanline, during scanning;
computing interpolated intensity values between the first and second measurements of the intensity of illumination; and
using the interpolated intensity values to modify the stored outputs of the imaging array.
